(19) United States
(12) Patent Application Publication
(10) Pub. No.: US 2002/0089011 A1
(43) Pub. Date: Jul. 11, 2002

(54) EEPROM CELL WITH A SINGLE POLYSILICON LEVEL AND A SELF-ALGNED TUNNEL AREA

(76) Inventor: JEAN-MICHEL MIRABEL, CABRIES (FR)

Correspondence Address: JAMES H MORRIS, WOLF G GREENFIELD AND SACKS, 600 ATLANTIC AVENUE, BOSTON, MA, 02210

(21) Appl. No.: 09/097,435

(22) Filed: Jun. 15, 1998

(30) Foreign Application Priority Data
Jun. 17, 1997 (FR) 97/07740

(51) Int. Cl. H01L 29/788

(52) U.S. Cl. 257/315

(57) ABSTRACT

The present invention relates to an EEPROM cell with a single polysilicon level which corresponds to a floating gate which extends, on the one hand, via a first insulating layer above a heavily-doped region of a first type of conductivity forming a control gate, on the other hand, via a second insulating layer to form a gate finger above a channel area of the cell. The second insulating layer is a sufficiently thin layer to allow a tunnel effect and the drain area of the cell has a gradual profile and partially extends under the gate finger.

### BACKGROUND OF THE INVENTION

1. Field of the Invention

The present invention relates to a single polysilicon level EEPROM-type memory cell.

2. Discussion of the Related Art

FIG. 1 shows in the form of a circuit diagram an EEPROM cell M associated with a selection transistor Tp. The selection transistor has a drain Dp, a source Sp, and a control gate Gp. The memory cell has a drain D connected to source Sp of the selection transistor, a floating gate FG, a control gate CG, and a source S. The floating gate includes an extension FG1 arranged above a tunnel oxide region and meant for the programming and the deleting of memory cell M, as will be explained hereafter in relation with FIGS. 2A and 2B.

FIG. 2A shows a top view of a conventional embodiment of a single polysilicon level EEPROM cell. FIG. 2B shows a cross-sectional view according to broken line BB of FIG. 2A.

Of course, FIGS. 2A and 2B are very simplified and are not drawn to scale as is usual in the field of the representation of semiconductor components.

Reference will be made hereafter to FIGS. 2A and 2B altogether. The structure is formed in a P-type substrate. The channel of transistor Tp extends under a polysilicon portion Gp. On either side of this channel region, N-type regions 10 and 11, respectively corresponding to drain and source regions Dp and Sp, extend. Region 11 extends to reach a region 13 corresponding to drain D of the memory cell. A source region 14 of the memory cell appears on the other side of a gate finger D1. A drain contact Dp is taken on region 10 and a source contact S is taken on region 14. Regions 10, 11, 13, 14, are delimited by thick oxide areas.

Gate finger D1 extends from a main floating gate portion FG, made of polysilicon, which rests upon an insulating layer formed on a heavily-doped N-type region 15 corresponding to the control gate of the memory cell and on which a contact with control gate CG is taken. In FIG. 2B, reference 18 designates a thick oxide area separating region 14 from region 15. Further, for the programming and the deleting of the memory cell, a second finger D2 extending from polysilicon area FG is provided. Finger D2 extends above a portion of N-type region 11, 13, and especially above a region 17, called the “tunnel area”, corresponding to a very thin oxide through which a tunnel effect may occur. It should be noted that all polysilicon regions result from the etching of the same polysilicon layer.

The cell operates as follows.

To place electrons in the floating gate, which corresponds to a deleted state, control gate CG of cell M and gate Gp of selection transistor Tp are placed at a high programming voltage VPP (for example, 15 volts), while drain Dp and source S are grounded. Then, transistor Tp is on and electrons will transit through the tunnel oxide layer into finger D2, that is, in floating gate FG. In this deleted state, cell M is normally blocked (non-conducting).

To place holes in the floating gate, which corresponds to a programmed state, gate Gp of the selection transistor is placed at VPP, which turns it on, control gate CG is placed at low voltage (ground), terminal Dp is placed at VPP and terminal S is maintained floating. Then, holes transit through tunnel oxide area 17 into finger D2 and on the floating gate. In this programmed state, cell M is normally on.

To read the cell, the selection transistor is turned on by placing its gate Gp at supply voltage VDD, for example, 5 volts, and drain Dp is positively biased with respect to source S (for example, 2 volts and 0 volt). Control gate CG is set to 5 volts. If the cell is in the deleted state, no current will flow from Dp to S. If the cell is in the programmed state, a current will flow from Dp to S. It should be understood that the selection transistor is used to block any current flow when the floating gate is charged with holes (programmed state) and is not addressed in the read mode.

The structure of this cell and its manufacturing are relatively complex. This is essentially due to the fact that any gate breakdown must be avoided during read phases, and thus, that finger D1 of the floating gate disposed above the memory cell channel is formed above a relatively thick oxide to ensure a sufficient breakdown voltage.

In prior art, this has led, as previously indicated, to separating the memory cell channel function (finger D1) from the memory cell tunnel effect programming function (finger D2), which results in a surface increase. Further, the formation of the tunnel area is relatively complex since it requires the superposition of several masks which are not self-aligned: the implantation mask of a heavily-doped N-type area 19 under the tunnel oxide (see FIG. 2B), the mask of the tunnel oxide region defining the thinned oxide area where the load circulation for the programming or the deleting is performed, and the mask of polysilicon finger D2 towards which the load flow is directed.

### SUMMARY OF THE INVENTION

Thus, the present invention provides a novel structure of single polysilicon level EEPROM cell in which the tunnel area is self-aligned with respect to the floating area.

Another object of the present invention is to provide a single polysilicon level EEPROM cell of lower surface than prior cells.

To achieve these and other objects, the present invention provides an EEPROM cell with a single polysilicon level which corresponds to a floating gate which extends, on the one hand, via a first insulating layer above a heavily-doped region of a first type of conductivity forming a control gate, on the other hand, via a second insulating layer to form a gate finger above a channel area of the cell. In this cell, the second insulating layer is a sufficiently thin layer to allow a tunnel effect and the drain area of the cell has a gradual profile and partially extends under the gate finger.

According to an embodiment of the present invention, the source area of the cell also has a gradual profile and partially extends under the gate finger.

According to an embodiment of the present invention, the second insulating layer is a silicon oxide layer of a thickness from 50 to 80 nm.

According to an embodiment of the present invention, the source and drain regions result from an implantation of phosphorus at a first dose and of arsenic at a second dose higher than the first dose, these implantations being followed by a drive-in anneal so that doping phosphorus atoms penetrate under the gate edges.

According to an embodiment of the present invention, the first dose is on the order of some 10¹⁴ at./cm² and the second dose is on the order of some 10¹5 at./cm².

The foregoing objects, features and advantages of the present invention will be discussed in detail in the following non-limiting description of specific embodiments in connection with the accompanying drawings.

### BRIEF DESCRIPTION OF THE DRAWINGS

FIG. 1 shows the diagram of a conventional single polysilicon level EEPROM cell associated with a selection transistor;

FIGS. 2A and 2B show a top view and a simplified cross-sectional view of a single polysilicon level EEPROM cell according to prior art; and

FIGS. 3A and 3B show a top view and a simplified cross-sectional view of a single polysilicon level EEPROM cell according to the present invention.

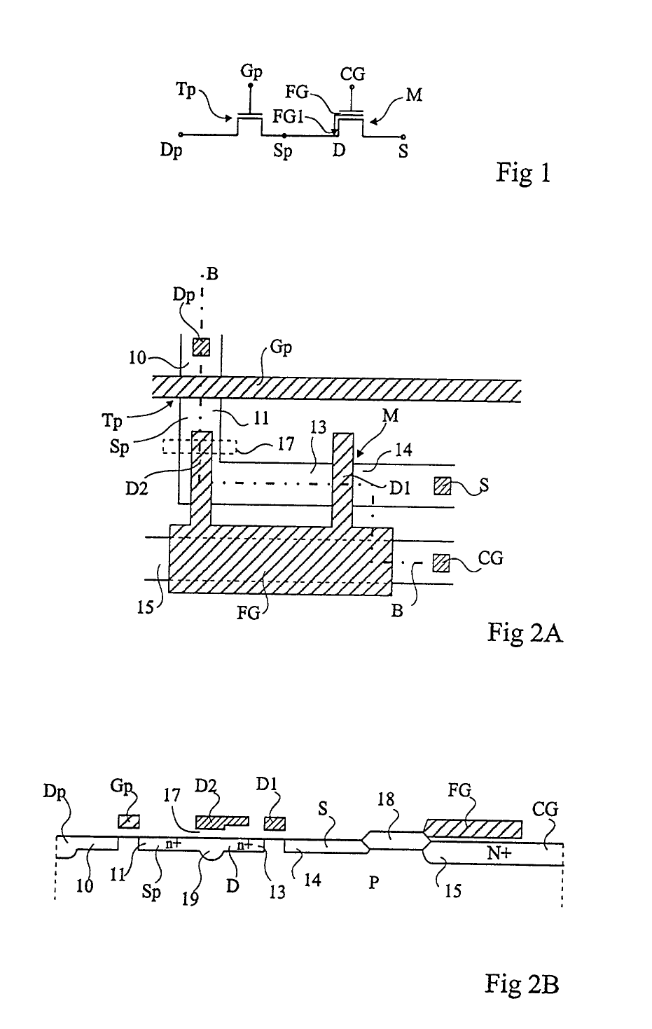

### DETAILED DESCRIPTION

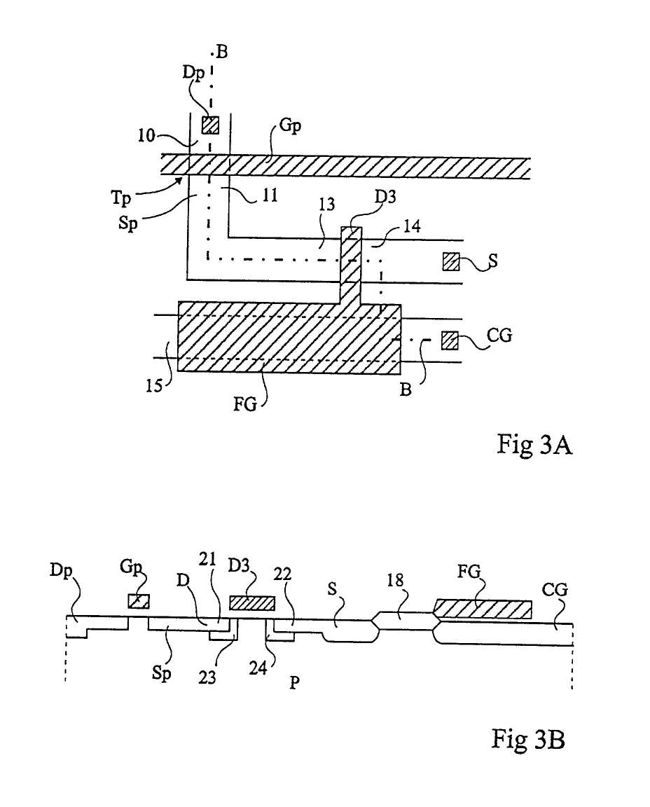

In FIGS. 3A and 3B, elements similar to those shown in FIGS. 2A and 2B are designated with same references. Reference Gp designates the gate of the selection transistor, reference Dp designates the drain of the selection transistor, reference Sp designates the source of the selection transistor, these elements being constituted as previously. Reference FG designates a portion of polysilicon formed, via an insulating layer, above an N-type diffused region 15 forming the control gate CG of the EEPROM cell, these elements being arranged as previously.

Conversely to what has been previously described, a single polysilicon finger D3 extends from floating gate FG, this finger defining a channel area between N-type portions 13 and 14 corresponding to the drain and to the source of the EEPROM cell. More specifically, each of regions 13, 14, includes a relatively heavily-doped N-type area 21, 22, substantially extending to above finger D3 and a more lightly-doped N-type area 23 partially extending under finger D3 on the drain side, as shown by the cross-sectional view of FIG. 3B. Preferably, although this is optional, a more lightly-doped N-type area 24 partially extending under finger D3 on the source side will also be provided. Such a structure can for example be obtained by performing successive implantations of phosphorus and arsenic, for example, at respective implantation densities on the order of some 10¹⁴ atoms/cm² and of some 10¹5 atoms/cm². During an anneal, the arsenic diffusion “pushes” the phosphorus diffusion and a concentration profile such that the surface concentration by the gate area is on the order of 10¹⁹ atoms/cm³, the junction depth is on the order of 0.4 to 0.5 μm, and the penetration under the gate is on the order of 0.3 μm is obtained. In other words, an N-type region penetrating under this gate, of an extent on the order of 0.3 μm, is located on either side of the gate.

Another difference between the present invention and the state of the art is that the insulator under gate finger D3 is a very thin oxide allowing a tunnel effect, that is, a silicon oxide of a thickness on the order of 60 to 80 μm.

If, in prior art, gate finger D1 has a width (channel length) on the order of 1 μm, to keep the same characteristics for the structure, gate finger D3 according to the present invention will have a width on the order of 1.6 μm (or of 1.3 μm only, if region 24 on the source side is omitted). The voltages applied in programming, deleting and reading of the structure according to the present invention will be the same as those mentioned previously in relation with FIGS. 2A and 2B. During programming, while the drain is at VPP, the source is floating and the gate is grounded, the injection of loads in the floating gate occurs through the areas where finger D3 covers drain extension portion 23. During deleting, while the drain and the source are grounded and the gate is at VPP, the injection of loads in the floating gate occurs through the areas where finger D3 covers drain and source extension areas 23 and 24.

Of course, the present invention is likely to have various alterations, modifications, and improvements which will readily occur to those skilled in the art. Especially, the various numerical values have been given as an example only and must only be considered as orders of magnitude likely to have wide variations linked to the manufacturing technologies used.

Such alterations, modifications, and improvements are intended to be part of this disclosure, and are intended to be within the spirit and the scope of the present invention. Accordingly, the foregoing description is by way of example only and is not intended to be limiting. The present invention is limited only as defined in the following claims and the equivalents thereto.

What is claimed is:

1. An EEPROM cell with a single polysilicon level which corresponds to a floating gate which extends, on the one hand, via a first insulating layer above a heavily-doped region of a first type of conductivity forming a control gate, and on the other hand, via a second insulating layer to form a gate finger above a channel area of the cell,
wherein the second insulating layer is a sufficiently thin layer to allow a tunnel effect and wherein the drain area of the cell has a gradual profile and partially extends under the gate finger.

2. The EEPROM cell of claim 1, wherein the source area of the cell also has a gradual profile and partially extends under the gate finger.

3. The EEPROM cell of claim 1, wherein the second insulating layer is a silicon oxide layer of a thickness from 50 to 80 nm.

4. The EEPROM cell of claim 2, wherein the source and drain regions result from an implantation of phosphorus at a first dose and of arsenic at a second dose higher than the first dose, these implantations being followed by a drive-in anneal so that doping phosphorus atoms penetrate under the gate edges.

5. The EEPROM cell of claim 4, wherein the first dose is on the order of some 10¹⁴ at./cm² and the second dose is on the order of some 10¹⁵ at./cm².
